(19) United States
(12) Patent Application Publication
(10) Pub. No.: US 2025/0126720 A1
(43) Pub. Date: Apr. 17, 2025

(54) CIRCUIT BOARD WITH ANGLED BEVEL

(71) Applicant: Dell Products L.P., Round Rock, TX (US)

(72) Inventors: Steven R. ETHRIDGE, Austin, TX (US); James L. PETIVAN, Austin, TX (US)

(73) Assignee: Dell Products L.P., Round Rock, TX (US)

(21) Appl. No.: 18/485,673

(22) Filed: Oct. 12, 2023

(51) Int. Cl. H05K 3/00

(52) U.S. Cl. CPC H05K 3/0044; H05K 2203/0228

(57) ABSTRACT

A method for processing a circuit board may include making an angled cut on an edge of the circuit board between a first surface and a second surface of the circuit board to form a bevel on the edge such that the first surface and the angled cut form an obtuse angle and the second surface and the angled cut form an acute angle.

### TECHNICAL FIELD

The present disclosure relates in general to information handling systems, and more particularly to systems and methods for creating an angled bevel on a circuit board, for example for use with coupling a straddle mount connector to the circuit board.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems utilize one or more circuit boards. Some circuit boards may have a connector known as a straddle mount connector, a receptacle connector coupled to the circuit board at an edge of the circuit board, and wherein the connector “straddles” both sides of the circuit board at such edge. Once mounted, the straddle mount connector may receive another circuit board having an edge connector configured to mate with the straddle mount connector, thus providing electrical coupling between both circuit boards.

In existing approaches, a circuit board may be beveled at its edges in locations in which a straddle mount connector may be placed. A bevel is a “V” shaped edge. When installing a straddle mount connector onto an edge with a bevel, the point of the “V” may enter the connector pin field first and may not contact the pins because the board is narrower than the height between the pins. In the event the connector contacts do touch the board, the beveled edge reduces the insertion forces, thus reducing potential for damage. As the connector is pushed further onto the board, the pins may eventually contact the board, and the bevel may act as a guide to help align the connector with the board. In traditional approaches, such beveling requires an extra step (and an additional cost) in the circuit board manufacturing process to cut two angled slopes at the edge of the circuit board to create the V-shaped bevel. To illustrate, FIG. 4 depicts a side elevation view of a portion of a circuit board 10, as is known in the art. As shown in FIG. 4, circuit board 10 may include a first surface 12 and second surface 14. To bevel an edge of circuit board 10 using traditional approaches, a first angled cut 16 may be made on first surface 12 proximate to the edge and a second angled cut 18 may be made on second surface 14 proximate to the edge. As a result, the bevel may form an obtuse angle θ₁ between the remainder of first surface 12 and first angled cut 16 and may form an obtuse angle θ₂ between the remainder of second surface 14 and second angled cut 18.

### SUMMARY

In accordance with the teachings of the present disclosure, the disadvantages and problems associated with existing approaches to mechanically mounting a straddle mount connector to a circuit board may be reduced or eliminated.

In accordance with embodiments of the present disclosure, a circuit board may include a first surface, a second surface, and an edge between the first surface and the second surface, the edge having a bevel comprising an angled cut formed between the first surface and the second surface such that the first surface and the angled cut form an obtuse angle and the second surface and the angled cut form an acute angle.

In accordance with these and other embodiments of the present disclosure, an information handling system may include a processor and an information handling resource communicatively coupled to the processor and comprising a circuit board including a first surface, a second surface, and an edge between the first surface and the second surface, the edge having a bevel comprising an angled cut formed between the first surface and the second surface such that the first surface and the angled cut form an obtuse angle and the second surface and the angled cut form an acute angle.

In accordance with these and other embodiments of the present disclosure, a method for processing a circuit board may include making an angled cut on an edge of the circuit board between a first surface and a second surface of the circuit board to form a bevel on the edge such that the first surface and the angled cut form an obtuse angle and the second surface and the angled cut form an acute angle.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example information handling system, in accordance with embodiments of the present disclosure;

FIG. 2 depicts a side elevation view of a portion of a circuit board with a bevel formed at an edge thereof, in accordance with embodiments of the present disclosure;

FIG. 3 illustrates a system for forming a bevel such as that shown in FIG. 2 at an edge of a circuit board, in accordance with embodiments of the present disclosure; and

FIG. 4 depicts a side elevation view of a portion of a circuit board, as is known in the art.

### DETAILED DESCRIPTION

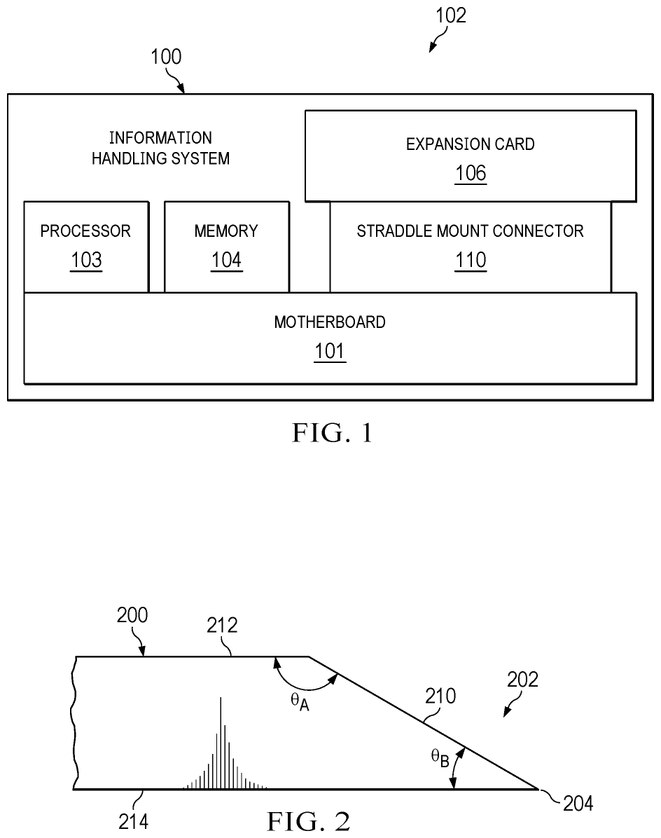

Preferred embodiments and their advantages are best understood by reference to FIGS. 1 through 3 wherein like numbers are used to indicate like and corresponding parts.

For the purposes of this disclosure, an information handling system may include any instrumentality or aggregate of instrumentalities operable to compute, classify, process, transmit, receive, originate, retrieve, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”), microcontroller, or hardware or software control logic. Additional components of the information handling system may include one or more storage one devices, or more communications ports for communicating with external devices as well as various input/output (“I/O”) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems (BIOSs), buses, memories, I/O devices and/or interfaces, storage resources, network interfaces, motherboards, and/or any other components and/or elements of an information handling system.

For the purposes of this disclosure, circuit boards may broadly refer to printed circuit boards (PCBs), printed wiring boards (PWBs), printed wiring assemblies (PWAs), etched wiring boards, and/or any other board or similar physical structure operable to mechanically support and electrically couple electronic components (e.g., packaged integrated circuits, slot connectors, etc.). A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

FIG. 1 illustrates a block diagram of selected components of an example information handling system 102. In some embodiments, information handling system 102 may comprise a server. In other embodiments, information handling system 102 may comprise networking equipment for facilitating communication over a communication network. In yet other embodiments, information handling system 102 may comprise a personal computer, such as a laptop, notebook, or desktop computer.

As shown in FIG. 1, information handling system 102 may include a chassis 100 that houses a motherboard 101, a processor 103 coupled to motherboard 101, a memory 104 coupled to motherboard 101, and an expansion card 106 mechanically and electrically coupled to motherboard 101 via a straddle mount connector 110 mechanically coupled to motherboard 101.

Chassis 100 may include any suitable housing or enclosure configured to house the various components of information handling system 102, and may be constructed from metal, plastic, and/or any other suitable material.

Motherboard 101 may comprise a circuit board configured to provide structural support for one or more information handling resources of information handling system 102 and/or electrically couple one or more of such information handling resources to each other and/or to other electric or electronic components external to information handling system 102.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in a storage resource, memory system 104, and/or another component of information handling system 102.

Memory 104 may be communicatively coupled to processor 103 and may comprise any system, device, or apparatus operable to retain program instructions or data for a period of time (e.g., computer-readable media). Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off. In particular embodiments, memory 104 may comprise dynamic random access memory (DRAM).

Straddle mount connector 110 may comprise a receptacle connector fixedly mounted relative to motherboard 101 on an edge of motherboard 101 and “straddling” both sides of motherboard 101 at such edge, and may be constructed to mechanically couple expansion card 106 within such straddle mount connector 110 and to electrically couple such expansion card 106 to motherboard 101, processor 103, and/or other components of information handling system 102. Straddle mount connector 110 may comprise a socket including a receptacle slot or other opening configured to removably receive a corresponding mating edge connector of an expansion card 106.

Expansion card 106 may comprise a circuit board configured to perform a particular functionality within information handling system 102. For example, in some embodiments, expansion card 106 may comprise a riser card.

In addition to motherboard 101, processor 103, memory 104, expansion card 106, and straddle mount connector 110, information handling system 102 may include one or more other information handling resources.

FIG. 2 depicts a side elevation view of a portion of a circuit board 200 with a bevel 202 formed at an edge 204 of circuit board 200, in accordance with embodiments of the present disclosure. In some embodiments, circuit board 200 may be used to implement motherboard 101 depicted in FIG. 1.

As shown in FIG. 2, circuit board 200 may include a first surface 212 and second surface 214. To bevel edge 204 of circuit board 200, a single angled cut 210 may be made between first surface 212 and second surface 214 proximate to edge 204. As a result, bevel 202 may form an obtuse angle θ_{A} between the remainder of first surface 212 and single angled cut 210 and may form an acute angle θ_{B} between the remainder of second surface 214 and single angled cut 210.

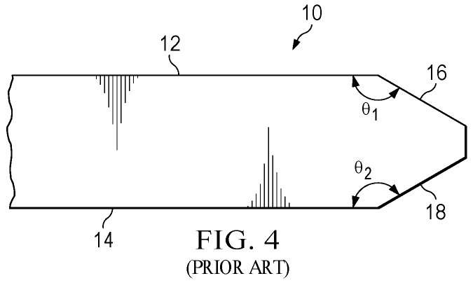

When mounting a straddle mount connector with a bevel 202 such as that depicted in FIG. 2, the connector may be offset downward slightly in the fixture used to mount it so that second surface 214 of circuit board 200, which sticks out more than first surface 212, does not interfere with the bottom pins of the connector. As the connector is pushed onto circuit board 200, the ramp of bevel 202 may assist in guiding the connector into place, similar to that of a traditional bevel as depicted in FIG. 4.

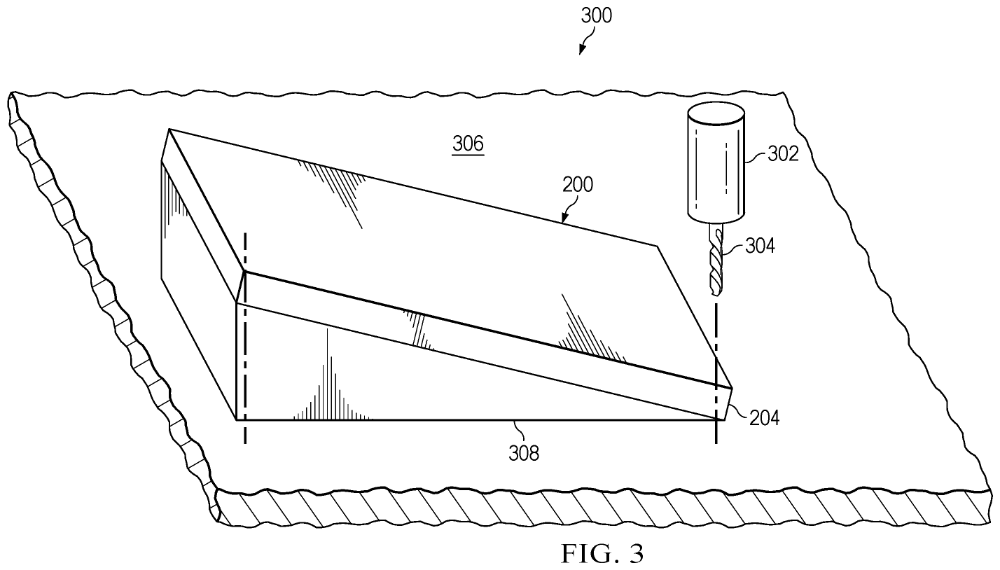

Creating bevel 202 depicted in FIG. 2 may leverage an existing step in a manufacturing process for circuit board 200, and thus may not require an additional manufacturing step as is the case with traditional circuit board edge bevels. For example, bevel 202 may be formed while routing edge 204 during the routing step of a manufacturing process for circuit board 200, as described in greater detail with respect to FIG. 3, below.

FIG. 3 illustrates a system 300 for forming bevel 202 at edge 204 of circuit board 200, in accordance with embodiments of the present disclosure. As shown in FIG. 3, system 300 may comprise a routing tool 302 having a blade 304, and a routing table 306 with an angled wedge 308 placed atop routing table 306. During routing of edge 204, circuit board 200 may be angled relative to routing table 306 (e.g., via wedge 308 having a desired ramp angle) such that blade 304 creates single angled cut 210 through circuit board 200 to create bevel 202.

Although FIG. 3 depicts a particular system 300 and method for creating single angled cut 210, any other suitable system and/or method may be used, including any other approaches for angling circuit board 200 relative to routing table 306 during routing of edge 204 and any approaches for angling circuit board 200 relative to blade 304.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112 (f) unless the words “means for” or “step for” are explicitly used in the particular claim.

What is claimed is:

1. A circuit board comprising:
a first surface;
a second surface; and
an edge between the first surface and the second surface, the edge having a bevel comprising an angled cut formed between the first surface and the second surface such that the first surface and the angled cut form an obtuse angle and the second surface and the angled cut form an acute angle.

2. The circuit board of claim 1, comprising a straddle mount connector mounted to the bevel.

3. An information handling system comprising:
a processor; and
an information handling resource communicatively coupled to the processor and comprising a circuit board including:
a first surface;
a second surface; and
an edge between the first surface and the second surface, the edge having a bevel comprising an angled cut formed between the first surface and the second surface such that the first surface and the angled cut form an obtuse angle and the second surface and the angled cut form an acute angle.

4. The information handling system of claim 3, the circuit board further comprising a straddle mount connector mounted to the bevel.

5. A method for processing a circuit board, comprising:
making an angled cut on an edge of the circuit board between a first surface and a second surface of the circuit board to form a bevel on the edge such that the first surface and the angled cut form an obtuse angle and the second surface and the angled cut form an acute angle.

6. The method of claim 5, the circuit board further comprising a straddle mount connector mounted to the bevel.

7. The method claim 5, further comprising using a blade of a routing tool to make the angled cut.

8. The method of claim 7, further comprising angling the circuit board relative to the blade to make the angled cut.

9. The method of claim 8, further comprising angling the circuit board relative to a routing table associated with the routing tool in order to angle the circuit board relative to the blade.

10. The method of claim 9, further comprising using a wedge placed on the routing table to angle the circuit board relative to the routing table.
